(19) United States
(12) Patent Application Publication
(10) Pub. No.: US 2025/0081518 A1
(43) Pub. Date: Mar. 6, 2025

(54) SEMICONDUCTOR DEVICE AND MANUFACTURING METHOD OF SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Yuki SHIBUTANI, Hakusan Ishikawa (JP)

(21) Appl. No.: 18/390,425

(22) Filed: Dec. 20, 2023

(30) Foreign Application Priority Data
Sep. 5, 2023 (JP) 2023-143985

(51) Int. Cl. H01L 29/78; H01L 29/06; H01L 29/40

(52) U.S. Cl. CPC H10D 30/668; H10D 62/107; H10D 64/01; H10D 64/117

(57) ABSTRACT

A semiconductor device includes first to fourth electrodes, first to fourth semiconductor regions, and first and second insulating parts. The first semiconductor region is located on the first electrode. The second semiconductor region is located on the first semiconductor region. The third semiconductor region is located on the second semiconductor region. The second electrode is located on the third semiconductor region. The third electrode is arranged with the second semiconductor region. The first insulating part is located between the second semiconductor region and the third electrode. The fourth electrode is arranged with the first semiconductor region and the third electrode. The second insulating part is located between the first semiconductor region and the fourth electrode and between the third electrode and the fourth electrode. The fourth semiconductor region is located under the third electrode. The fourth semiconductor region is electrically connected with the second electrode.

### CROSS-REFERENCE TO RELATED APPLICATIONS

This application is based upon and claims the benefit of priority from Japanese Patent Application No. 2023-143985, filed on Sep. 5, 2023; the entire contents of which are incorporated herein by reference.

### FIELD

Embodiments described herein relate generally to a semiconductor device and a manufacturing method of a semiconductor device.

### BACKGROUND

A semiconductor device such as a MOSFET (Metal Oxide Semiconductor Field Effect Transistor) or the like is used in power conversion and the like. It is desirable for the on-resistance of the semiconductor device to be low.

### BRIEF DESCRIPTION OF THE DRAWINGS

FIG. 1 is a plan view illustrating a semiconductor device according to a first embodiment;

FIG. 2 is a plan view illustrating a portion of the semiconductor device according to the first embodiment;

FIG. 3 is a cross-sectional view illustrating a portion of the semiconductor device according to the first embodiment;

FIG. 4 is a cross-sectional view illustrating a portion of the semiconductor device according to the first embodiment;

FIG. 5 is a graph illustrating simulation results of the semiconductor device according to the first embodiment;

FIG. 6 is a plan view illustrating a portion of a semiconductor device according to a first modification of the first embodiment;

FIG. 7 is a cross-sectional view illustrating a portion of the semiconductor device according to the first modification of the first embodiment;

FIG. 8 is a cross-sectional view illustrating a portion of the semiconductor device according to the first modification of the first embodiment;

FIG. 9 is a cross-sectional view illustrating a portion of a semiconductor device according to a second modification of the first embodiment;

FIG. 10 is a plan view illustrating a portion of a semiconductor device according to a second embodiment;

FIG. 11 is a cross-sectional view illustrating a portion of the semiconductor device according to the second embodiment;

FIG. 12 is a cross-sectional view illustrating a portion of the semiconductor device according to the second embodiment;

FIG. 13 is a plan view illustrating a portion of a semiconductor device according to a third embodiment;

FIG. 14 is a cross-sectional view illustrating a portion of the semiconductor device according to the third embodiment;

FIGS. 15A to 15D are cross-sectional views illustrating an example of a manufacturing method of a semiconductor device according to an embodiment;

FIGS. 16A to 16C are cross-sectional views illustrating an example of a manufacturing method of a semiconductor device according to an embodiment;

FIGS. 17A to 17D are cross-sectional views illustrating another example of a manufacturing method of the semiconductor device according to the embodiment; and

FIG. 18A and FIG. 18B are cross-sectional views illustrating another example of a manufacturing method of the semiconductor device according to the embodiment.

### DETAILED DESCRIPTION

A semiconductor device according to an embodiment includes a first electrode, a first semiconductor region of a first conductivity type, a second semiconductor region of a second conductivity type, a third semiconductor region of the first conductivity type, a second electrode, a third electrode, a first insulating part, a fourth electrode, a second insulating part, and a fourth semiconductor region of the second conductivity type. The first semiconductor region is located on the first electrode. The second semiconductor region is located on the first semiconductor region. The third semiconductor region is selectively located on the second semiconductor region. The second electrode is located on the third semiconductor region. The second electrode is electrically connected with the third semiconductor region. The third electrode is arranged with the second semiconductor region in a second direction and a third direction. The second direction is perpendicular to a first direction; and the first direction is from the first electrode toward the second electrode. The third direction is perpendicular to the first and second directions. The first insulating part is located between the second semiconductor region and the third electrode in the second and third directions. The fourth electrode is arranged with the first semiconductor region and the third electrode in the second and third directions. The second insulating part is located between the first semiconductor region and the fourth electrode and between the third electrode and the fourth electrode in the second and third directions. The fourth semiconductor region is located under the third electrode. The fourth semiconductor region is electrically connected with the second electrode.

A manufacturing method of a semiconductor device according to an embodiment includes a first process, a second process, and a third process. In the first process, a pillar region of a second conductivity type is formed in a semiconductor region of a first conductivity type. In the second process, a first conductive part is formed adjacent to the pillar region. In the third process, a second conductive part is formed on the pillar region.

A manufacturing method of a semiconductor device according to an embodiment includes a first process, a second process, and a third process. In the first process, a first conductive part is formed in a semiconductor region of a first conductivity type. In the second process, a pillar region of a second conductivity type is formed adjacent to the first conductive part. In the third process, a second conductive part is formed on the pillar region.

Hereinafter, the embodiments of the invention will be described with reference to the drawings.

The drawings are schematic or conceptual, and the relationship between the thicknesses and widths of respective portions, the ratio of the sizes between the portions, and the like are not necessarily the same as the actual ones. Even in a case where the same portions are represented, the dimensions and the ratios of the respective portions in the drawings may be represented differently.

In the specification and the drawings, the same elements as those already described are denoted by the same reference numerals, and detailed description of the elements will be omitted as appropriate.

In the following description and drawings, the notations n⁺, n⁻, p⁺, and p represent the relative levels of each impurity concentration. That is, the notation attached with “+” represents to have a relatively higher impurity concentration than the notation not attached with any one of “+” and “−”, and the notation attached with “−” represents to have a relatively lower impurity concentration than the notation not attached with any one of “+” and “−”. These notations represent the relative levels of net impurity concentrations after the impurities have compensated for each other when impurities to be acceptors and impurities to be donors are contained in each region.

With respect to each of the embodiments described below, the p type and the n type of each semiconductor region may be inverted to carry out each of the embodiments.

### First Embodiment

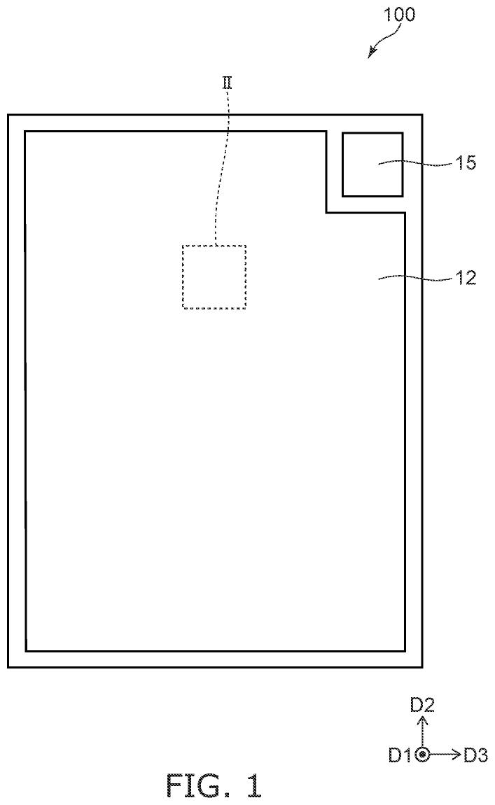

FIG. 1 is a plan view illustrating a semiconductor device according to a first embodiment.

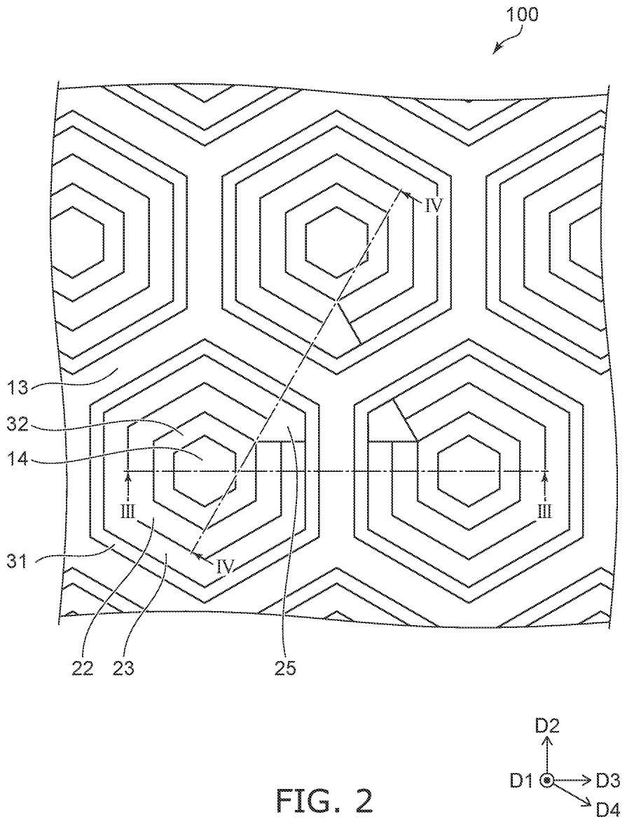

FIG. 2 is a plan view illustrating a portion of the semiconductor device according to the first embodiment.

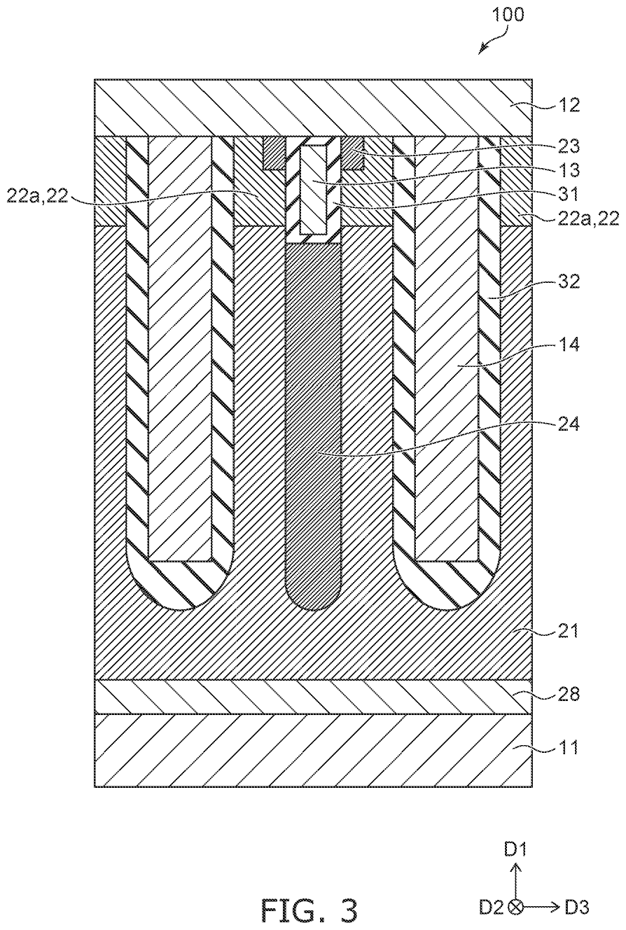

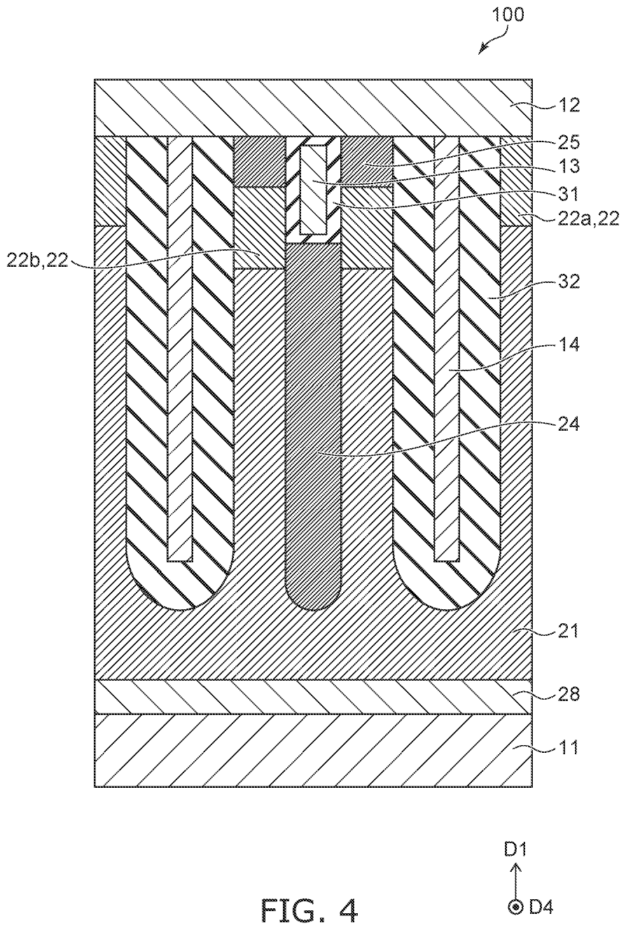

FIGS. 3 and 4 are cross-sectional views illustrating portions of the semiconductor device according to the first embodiment.

FIG. 2 illustrates region II shown in FIG. 1.

FIG. 3 is a cross-sectional view along line III-III shown in FIG. 2.

FIG. 4 is a cross-sectional view along line IV-IV shown in FIG. 2.

The semiconductor device 100 according to the first embodiment is a vertical MOSFET. The semiconductor device 100 is a MOSFET having a so-called dot FP structure.

As illustrated in FIGS. 1 to 4, the semiconductor device 100 includes a drain electrode 11 (a first electrode), a source electrode 12 (a second electrode), a gate electrode 13 (a third electrode), a FP electrode 14 (a fourth electrode), a gate pad 15, an n-type drift region 21 (a first semiconductor region), a p-type base region 22 (a second semiconductor region), an n⁺-type source region 23 (a third semiconductor region), a p-type pillar region 24 (a fourth semiconductor region), a p⁺-type connection region 25 (a fifth semiconductor region), an n⁺-type drain region 28, a gate insulating part 31 (a first insulating part), and a FP insulating part 32 (a second insulating part). In the semiconductor device 100, the first conductivity type is the n-type; and the second conductivity type is the p-type. The source electrode 12 is not illustrated in FIG. 2.

A first direction D1, a second direction D2, and a third direction D3 are used in the description of the following embodiments. The direction from the drain electrode 11 toward the source electrode 12 is taken as the first direction D1. One direction perpendicular to the first direction D1 is taken as the second direction D2. A direction perpendicular to the first and second directions D1 and D2 is taken as the third direction D3. A direction that is perpendicular to the first direction D1 and crosses the second direction D2 is taken as a fourth direction D4. The fourth direction D4 may be the same as or different from the third direction. Although the direction from the drain electrode 11 toward the source electrode 12 is referred to as “up/above/higher than”, and the opposite direction is referred to as “down/below/lower than” for easier understanding of the description, these directions are independent of the direction of gravity. Being viewed from above is referred to as “viewed in plan”.

As illustrated in FIG. 1, the source electrode 12 and the gate pad 15 are located at the upper surface of the semiconductor device 100. The source electrode 12 and the gate pad 15 are electrically isolated from each other.

As illustrated in FIGS. 3 and 4, the drain electrode 11 is located at the lower surface of the semiconductor device 100. The n⁻-type drift region 21 is located on the drain electrode 11 with the n⁺-type drain region 28 interposed. The n⁻-type drift region 21 is electrically connected with the drain electrode 11 via the n⁺-type drain region 28. The p-type base region 22 is located on the n⁻-type drift region 21. The n⁺-type source region 23 and the p⁺-type connection region 25 are selectively located on the p-type base region 22. The source electrode 12 is located on the p-type base region 22 and the n⁺-type source region 23. The source electrode 12 is electrically connected with the p-type base region 22 and the n⁺-type source region 23.

The gate electrode 13 is arranged with the p-type base region 22 in the second and third directions D2 and D3. In the semiconductor device 100, a portion of the gate electrode 13 is arranged with a portion of the n⁻-type drift region 21 in the second and third directions D2 and D3. In the semiconductor device 100, a portion of the gate electrode 13 is arranged with a portion of the n⁺-type source region 23 in the second and third directions D2 and D3.

The gate insulating part 31 is located between the gate electrode 13 and the p-type base region 22 in the second and third directions D2 and D3. In the semiconductor device 100, a portion of the gate insulating part 31 is located between the gate electrode 13 and the n⁻-type drift region 21 in the second and third directions D2 and D3. A portion of the gate insulating part 31 is located between the gate electrode 13 and the n⁺-type source region 23 in the second and third directions D2 and D3. A portion of the gate insulating part 31 is located between the gate electrode 13 and the p-type pillar region 24 in the first direction D1. A portion of the gate insulating part 31 is located between the gate electrode 13 and the source electrode 12 in the first direction D1. Thus, the gate electrode 13 is surrounded with the gate insulating part 31. The gate electrode 13 is located inside the gate insulating part 31.

The gate electrode 13 is electrically connected with the gate pad 15. The gate pad 15 is electrically isolated from the source electrode 12. The gate electrode 13 may be electrically connected with the gate pad 15 via a not-illustrated gate wiring layer.

The FP electrode 14 is arranged with the n⁻-type drift region 21 and the gate electrode 13 in the second and third directions D2 and D3. In the semiconductor device 100, a portion of the FP electrode 14 is arranged with the p-type base region 22 in the second and third directions D2 and D3. A portion of the FP electrode 14 is arranged with the n⁺-type source region 23 in the second and third directions D2 and D3.

The FP insulating part 32 is located between the FP electrode 14 and the n⁻-type drift region 21 and between the FP electrode 14 and the gate electrode 13 in the second and third directions D2 and D3. In the semiconductor device 100, a portion of the FP insulating part 32 is located between the FP electrode 14 and the p-type base region 22 in the second and third directions D2 and D3. A portion of the FP insulating part 32 is located between the FP electrode 14 and the n⁺-type source region 23 in the second and third directions D2 and D3. A portion of the FP insulating part 32 is located between the FP electrode 14 and the n⁻-type drift region 21 in the first direction D1. Thus, the FP electrode 14 is surrounded with the FP insulating part 32. The FP electrode 14 is located inside the FP insulating part 32. The FP electrode 14 is electrically connected with the source electrode 12.

The p-type pillar region 24 is located under the gate electrode 13. The p-type pillar region 24 functions as a super junction structure. The p-type pillar region 24 is arranged with the n⁻-type drift region 21 and the FP electrode 14 in the second and third directions D2 and D3. For example, the lower end of the p-type pillar region 24 is positioned lower than the lower end of the FP electrode 14. In the semiconductor device 100, the lower end of the p-type pillar region 24 is arranged with the lower end of the FP insulating part 32 in the second and third directions D2 and D3.

The p-type pillar region 24 is electrically connected with the source electrode 12. In the semiconductor device 100, the p-type pillar region 24 is electrically connected with the source electrode 12 via the p-type base region 22 and the p⁺-type connection region 25. The p-type base region 22 includes a first region 22a and a second region 22b. The lower end of the first region 22a is positioned higher than the upper end of the p-type pillar region 24. The lower end of the second region 22b is positioned lower than the upper end of the p-type pillar region 24. The second region 22b is arranged with the p-type pillar region 24 in the second and third directions D2 and D3. The p⁺-type connection region 25 is located on the second region 22b.

The p⁺-type connection region 25 is arranged with the gate electrode 13 in the second and third directions D2 and D3. The p⁺-type connection region 25 is arranged with the FP electrode 14 in the second and third directions D2 and D3. The p⁺-type connection region 25 is arranged with the n⁺-type source region 23 and the first region 22a of the p-type base region 22 in the second and third directions D2 and D3.

In the semiconductor device 100 as illustrated in FIG. 2, multiple FP electrodes 14 and multiple FP insulating parts 32 are arranged when viewed in plan. The FP electrodes 14 are arranged in an equilateral triangular configuration when viewed in plan. For example, the FP electrodes 14 may be arranged in a quadrilateral configuration when viewed in plan. The gate electrode 13 is located between the multiple FP electrodes 14.

In the semiconductor device 100 as illustrated in FIG. 2, the FP electrode 14 and the FP insulating part 32 are hexagonal when viewed in plan. The FP electrode 14 and the FP insulating part 32 may be, for example, triangular, quadrilateral, etc., when viewed in plan. In the semiconductor device 100, the gate insulating part 31 and the n⁺-type source region 23 are hexagonal when viewed in plan. The gate insulating part 31 and the n⁺-type source region 23 may be, for example, triangular, quadrilateral, etc., when viewed in plan.

An operation of the semiconductor device 100 will now be described.

A voltage that is not less than a threshold is applied to the gate electrode 13 in a state in which a positive voltage with respect to the source electrode 12 is applied to the drain electrode 11. As a result, a channel (an inversion layer) is formed in the p-type base region 22; and the semiconductor device 100 is set to an on-state. Electrons flow from the source electrode 12 toward the drain electrode 11 via the channel. Subsequently, when the voltage applied to the gate electrode 13 drops below the threshold, the channel in the p-type base region 22 disappears, and the semiconductor device 100 is set to an off-state.

When the semiconductor device 100 is switched to the off-state, the positive voltage with respect to the source electrode 12 that is applied to the drain electrode 11 increases. In other words, the potential difference between the n⁻-type drift region 21 and the FP electrode 14 increases. Due to the increase of the potential difference, a depletion layer spreads toward the n⁻-type drift region 21 from the interface between the FP insulating part 32 and the n⁻-type drift region 21. The spreading of the depletion layer can increase the breakdown voltage of the semiconductor device 100. Or, the on-resistance of the semiconductor device 100 can be reduced by increasing the concentration of the impurity that forms donors in the n⁻-type drift region 21 while maintaining the breakdown voltage of the semiconductor device 100.

When the semiconductor device 100 is in the off-state and a positive potential with respect to the potential of the source electrode 12 is applied to the drain electrode 11, a depletion layer spreads along the second and third directions D2 and D3 from the p-n junction surface of the p-type pillar region 24 and the n⁻-type drift region 21. The breakdown voltage of the semiconductor device 100 can be increased by the spreading of the depletion layer. Or, the concentration of the impurity that forms donors in the n⁻-type drift region 21 can be increased and the on-resistance of the semiconductor device 100 can be reduced while maintaining the breakdown voltage of the semiconductor device 100.

Examples of the materials of the components of the semiconductor device 100 will now be described.

The drain electrode 11, the source electrode 12, and the gate pad 15 include metals such as aluminum, copper, etc.

The n⁻-type drift region 21, the p-type base region 22, the n⁺-type source region 23, the p-type pillar region 24, the p⁺-type connection region 25, and the n⁺-type drain region 28 include silicon, silicon carbide, gallium nitride, or gallium arsenide as a semiconductor material. When silicon is used as the semiconductor material, arsenic, phosphorus, or antimony can be used as an impurity that forms donors. Boron can be used as an impurity that forms acceptors.

The gate electrode 13 and the FP electrode 14 include conductive materials such as polysilicon, etc. Impurities may be added to the conductive materials.

The gate insulating part 31 and the FP insulating part 32 include insulating materials. The gate insulating part 31 and the FP insulating part 32 include, for example, silicon oxide or silicon nitride.

Effects of the first embodiment will now be described.

In the semiconductor device 100, multiple FP electrodes 14 are arranged in the second and third directions D2 and D3. According to this structure, compared to when the FP electrodes 14 extend to be continuous in one direction, the volume of the n⁻-type drift region 21 used as the current path can be increased. The on-resistance of the semiconductor device 100 can be reduced thereby. In the semiconductor device 100, multiple gate electrodes 13 also are arranged in the second and third directions D2 and D3. According to this structure, compared to when the gate electrodes 13 extend to be continuous in one direction, channels are formed in more regions. The channel density is increased, and the on-resistance of the semiconductor device 100 is further reduced. For example, when the on-resistance of the semiconductor device 100 is reduced, the current density that flows through the semiconductor device 100 can be increased. By increasing the current density, the semiconductor device 100 can be smaller. Or, the number of the semiconductor devices 100 necessary to allow a prescribed current to flow can be reduced.

In the semiconductor device 100 as illustrated in FIGS. 3 and 4, the p-type pillar region 24 is located under the gate electrode 13. When the semiconductor device 100 is off, for example, a potential difference is provided between the p-type pillar region 24 and the region of the n⁻-type drift region 21 (hereinbelow, called the “n-type pillar region”) arranged with the p-type pillar region 24 in the second and third directions D2 and D3 so that the potential of the n-type pillar region is greater than the potential of the p-type pillar region 24. The impurity concentration of the n-type pillar region and the impurity amount of the p-type pillar region 24 inside a unit cell are substantially equal. Therefore, depletion layers extend in the p-type pillar region 24 side and the n-type pillar region side from the p-n junction interface formed by the p-type pillar region 24 and the n-type pillar region; and each p-type pillar region 24 and each n-type pillar region are depleted at a prescribed voltage. As a result, the concentration of the impurity that forms donors in the n⁻-type drift region 21 can be increased, the on-resistance of the semiconductor device 100 can be reduced, and the breakdown voltage can be increased.

By including the p-type pillar region 24 under the gate electrode 13, the area of the gate electrode 13 and the drain electrode 11 facing (overlapping) each other can be reduced, and the capacitance ratio between the gate electrode 13 and the drain electrode 11 can be reduced.

In the semiconductor device 100 as illustrated in FIGS. 3 and 4, the lower end of the p-type pillar region 24 is positioned lower than the lower end of the FP electrode 14. The on-resistance of the semiconductor device 100 can be further reduced thereby.

In the semiconductor device 100 as illustrated in FIG. 4, the p-type pillar region 24 is electrically connected with the source electrode 12 via the p⁺-type connection region 25 that is located on the p-type base region 22 (the second region 22b). As a result, the semiconductor device 100 is easily manufactured because it is unnecessary for the gate wiring part to be multilevel wiring. The gate resistance can be lowered because the volume of the gate electrode 13 is increased.

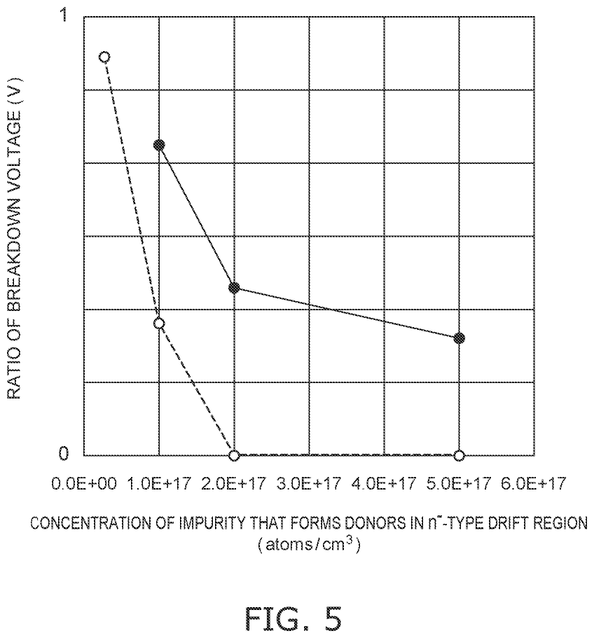

FIG. 5 is a graph illustrating simulation results of the semiconductor device according to the first embodiment.

In FIG. 5, the breakdown voltage ratio at the impurity concentrations of the semiconductor device 100 is illustrated by a solid line; and the breakdown voltage ratio at each impurity concentration of a reference example not including the p-type pillar region 24 is illustrated by a broken line.

As illustrated in FIG. 5, in the semiconductor device 100 including the p-type pillar region 24, compared to the reference example not including the p-type pillar region 24, the breakdown voltage does not easily decrease even when the concentration of the impurity that forms donors in the n⁻-type drift region 21 becomes high.

### First Modification

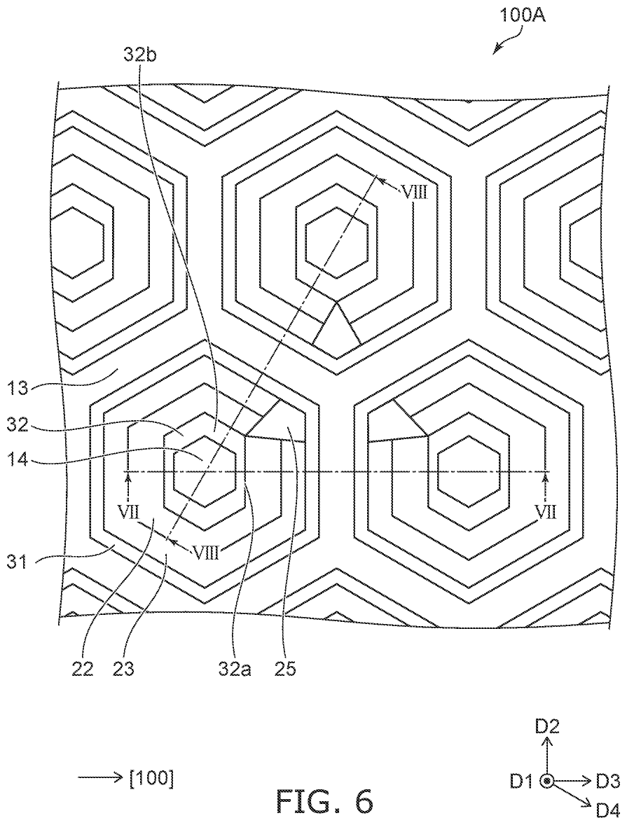

FIG. 6 is a plan view illustrating a portion of a semiconductor device according to a first modification of the first embodiment.

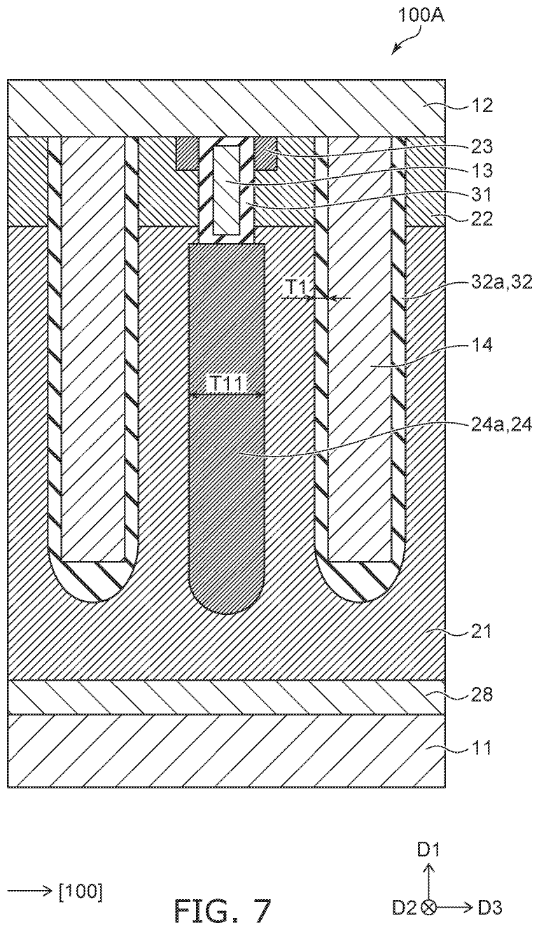

FIG. 7 is a cross-sectional view illustrating a portion of the semiconductor device according to the first modification of the first embodiment.

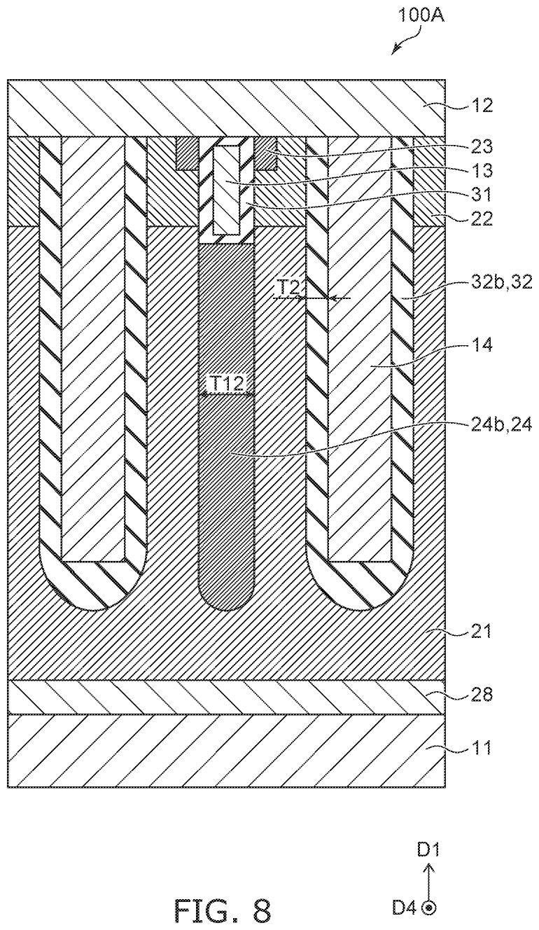

FIG. 8 is a cross-sectional view illustrating a portion of the semiconductor device according to the first modification of the first embodiment.

FIG. 6 illustrates a region corresponding to region II shown in FIG. 1.

FIG. 7 is a cross-sectional view along line VII-VII shown in FIG. 6.

FIG. 8 is a cross-sectional view along line VIII-VIII shown in FIG. 6.

As illustrated in FIGS. 6 to 8, the thickness of the FP insulating part 32 and the thickness of the p-type pillar region 24 of the semiconductor device 100A according to the first modification of the first embodiment are different from those of the semiconductor device 100. Otherwise, the semiconductor device 100A is the same as the semiconductor device 100.

The FP insulating part 32 includes a first insulating region 32a and a second insulating region 32b. The first insulating region 32a extends along the second direction D2. The second insulating region 32b extends along the fourth direction D4. A thickness T1 of the first insulating region 32a is less than a thickness T2 of the second insulating region 32b. The thickness T1 is the thickness in a direction (the third direction D3) perpendicular to the first direction D1 and the direction (the second direction D2) in which the first insulating region 32a extends. The thickness T2 is the thickness in a direction perpendicular to the first direction D1 and the direction (the fourth direction D4) in which the second insulating region 32b extends.

The p-type pillar region 24 includes a first portion 24a and a second portion 24b. The first portion 24a extends along the second direction D2. The first portion 24a is along the first insulating region 32a. The second portion 24b extends along the fourth direction D4. The second portion 24b is along the second insulating region 32b. A thickness T11 of the first portion 24a is greater than a thickness T12 of the second portion 24b. The thickness T11 is the thickness in a direction (the third direction D3) perpendicular to the first direction D1 and the direction (the second direction D2) in which the first portion 24a extends. The thickness T12 is the thickness in a direction perpendicular to the first direction D1 and the direction (the fourth direction D4) in which the second portion 24b extends.

For example, when the n-type drift region 21 includes silicon, the silicon oxidation rate tends to be different between the silicon crystal plane orientations. Specifically, the oxidation rate in the (100) plane of the silicon crystal tends to be slower than the oxidation rate in planes oblique to the (100) plane. Therefore, the thickness of the FP insulating part 32 at the plane along the (100) plane tends to be less than the thickness of the FP insulating part 32 in planes oblique to the (100) plane. For example, when the (100) plane is along the second direction D2, the thickness T1 of the first insulating region 32a extending along the second direction D2 tends to be less than the thickness T2 of the second insulating region 32b extending along a direction (e.g., the fourth direction D4) oblique to the second direction D2.

In the semiconductor device 100A, the thickness T11 of the first portion 24a is greater than the thickness T12 of the second portion 24b when the thickness T1 of the first insulating region 32a is less than the thickness T2 of the second insulating region 32b. As a result, the thickness of the p-type pillar region 24 can be increased in the region where the FP insulating part 32 tends to be thin; and the breakdown voltage can be increased.

### Second Modification

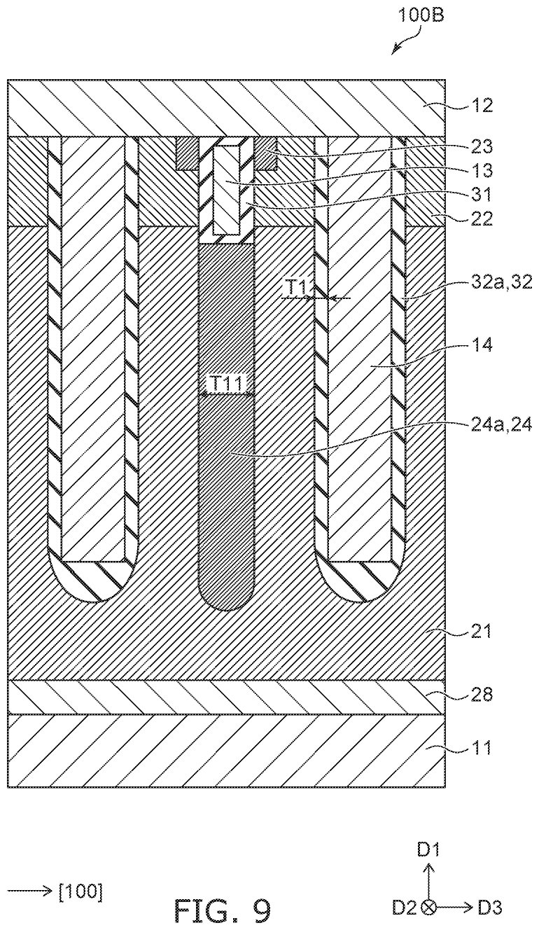

FIG. 9 is a cross-sectional view illustrating a portion of a semiconductor device according to a second modification of the first embodiment.

FIG. 9 illustrates a cross section at a position corresponding to line VII-VII shown in FIG. 6.

As illustrated in FIG. 9, the impurity concentration and thickness of the p-type pillar region 24 of the semiconductor device 100B according to the second modification of the first embodiment are different from those of the semiconductor device 100A. Otherwise, the semiconductor device 100B is the same as the semiconductor device 100A.

In the semiconductor device 100B, the thickness T11 of the first portion 24a is equal to the thickness T12 of the second portion 24b. On the other hand, the concentration of the impurity that forms donors in the first portion 24a is greater than the concentration of the impurity that forms donors in the second portion 24b.

In the semiconductor device 100B, the concentration of the impurity that forms donors in the first portion 24a is made greater than the concentration of the impurity that forms donors in the second portion 24b when the thickness T1 of the first insulating region 32a is less than the thickness T2 of the second insulating region 32b. As a result, the concentration of the impurity that forms donors in the p-type pillar region 24 can be increased in the region where the FP insulating part 32 tends to be thin; and the breakdown voltage can be increased.

### Second Embodiment

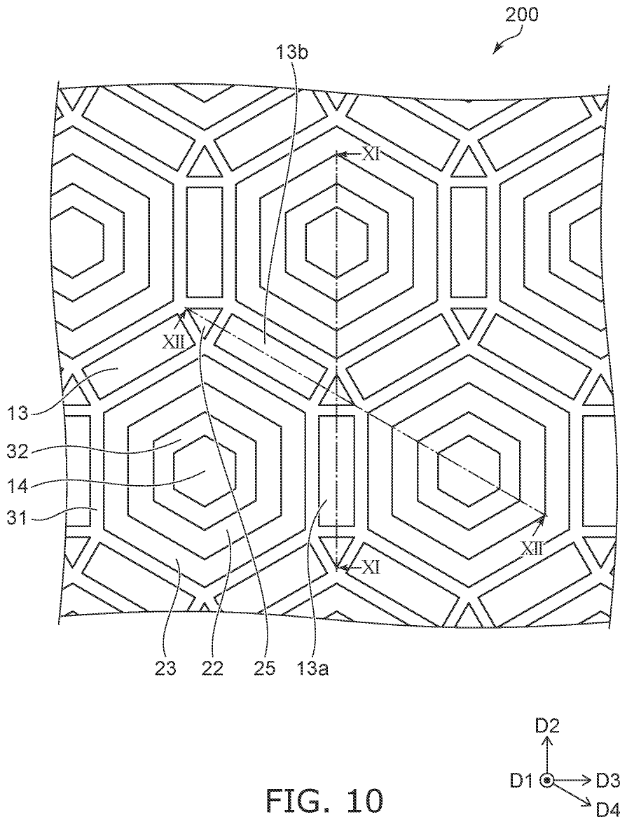

FIG. 10 is a plan view illustrating a portion of a semiconductor device according to a second embodiment.

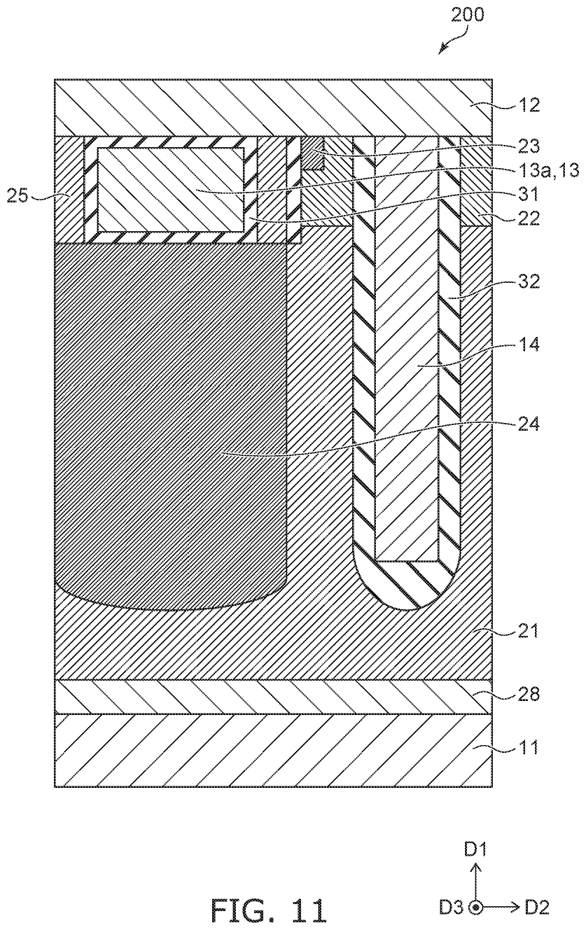

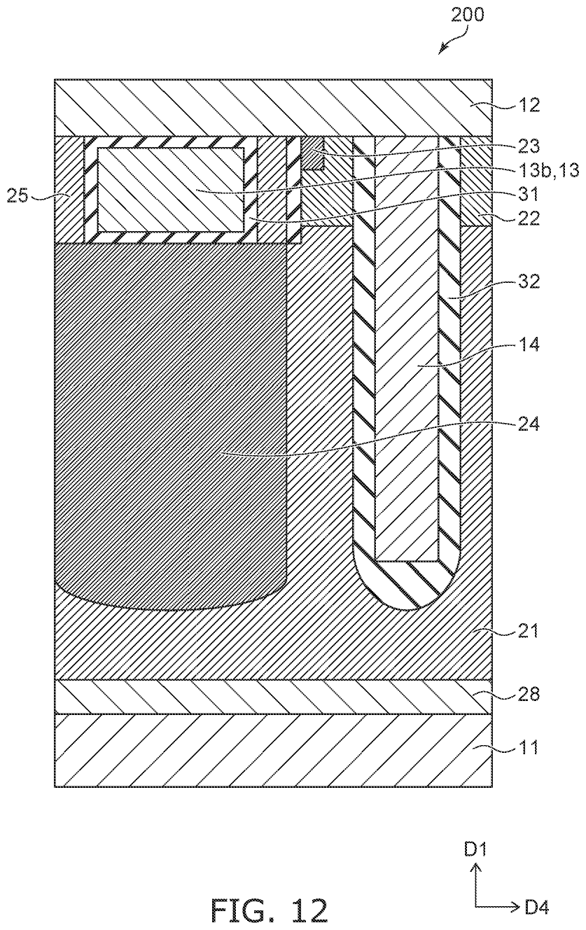

FIGS. 11 and 12 are cross-sectional views illustrating portions of the semiconductor device according to the second embodiment.

FIG. 10 illustrates a region corresponding to region II shown in FIG. 1.

FIG. 11 is a cross-sectional view along line XI-XI shown in FIG. 10.

FIG. 12 is a cross-sectional view along line XII-XII shown in FIG. 10.

As illustrated in FIGS. 10 to 12, the position of the p⁺-type connection region 25 of the semiconductor device 200 according to the second embodiment is different from that of the semiconductor device 100. Otherwise, the semiconductor device 200 is the same as the semiconductor device 100.

In the semiconductor device 200, the p-type pillar region 24 is electrically connected with the source electrode 12 via the p⁺-type connection region 25. The p⁺-type connection region 25 is located on the p-type pillar region 24. The p⁺-type connection region 25 is arranged with the gate electrode 13 in the second and third directions D2 and D3. The p⁺-type connection region 25 is arranged with the FP electrode 14 in the second and third directions D2 and D3. The p⁺-type connection region 25 is arranged with the p-type base region 22 and the n⁺-type source region 23 in the second and third directions D2 and D3.

The gate electrode 13 includes a first electrode region 13a and a second electrode region 13b. The first electrode region 13a extends along the second direction D2. The second electrode region 13b extends along the fourth direction D4. The p⁺-type connection region 25 is arranged with the first electrode region 13a in the second direction D2. The p⁺-type connection region 25 is arranged with the second electrode region 13b in the fourth direction D4. The p⁺-type connection region 25 is located at a position at which the gate electrodes 13 cross.

At the position at which the gate electrodes 13 cross in the dot FP structure, the gate electrode 13 does not face the p-type base region 22 or the n⁺-type source region 23; and a channel is not formed. Therefore, by locating the p⁺-type connection region 25 at the position at which the gate electrodes 13 cross, the p-type pillar region 24 can be electrically connected with the source electrode 12 by utilizing a region in which a channel is not formed. As a result, holes can be removed at a location in which a channel is not formed, and holes can be removed in a low-resistance region.

### Third Embodiment

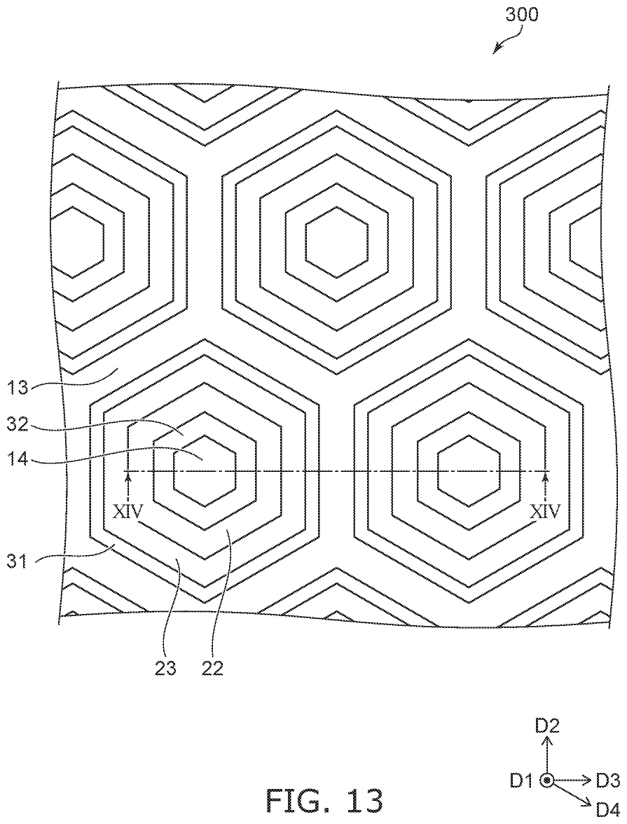

FIG. 13 is a plan view illustrating a portion of a semiconductor device according to a third embodiment.

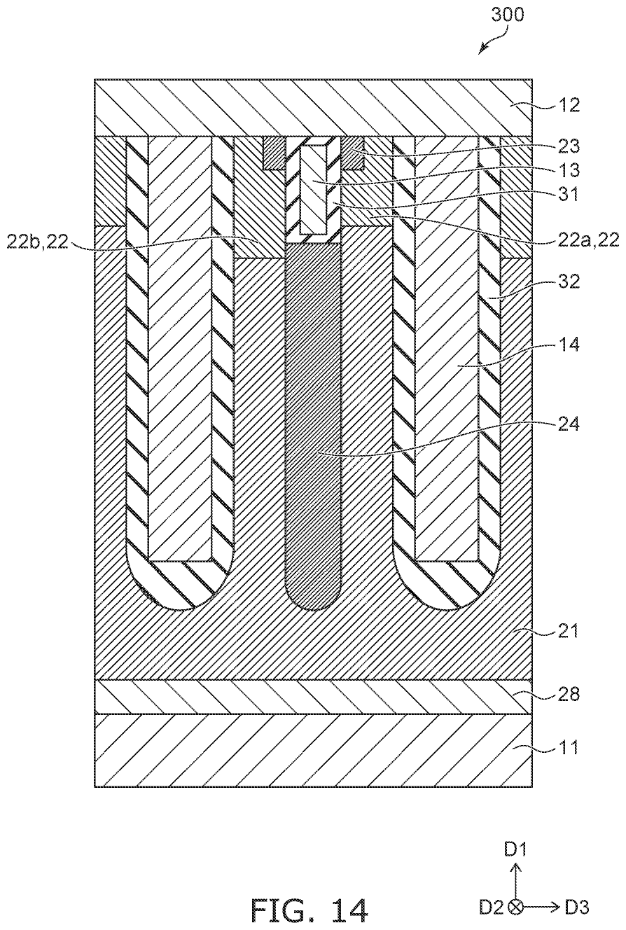

FIG. 14 is a cross-sectional view illustrating a portion of the semiconductor device according to the third embodiment.

FIG. 13 illustrates a region corresponding to region II shown in FIG. 1.

FIG. 14 is a cross-sectional view along line XII-XIV shown in FIG. 13.

As illustrated in FIGS. 13 and 14, the semiconductor device 300 according to the third embodiment differs from the semiconductor device 100 in that the p⁺-type connection region 25 is not included. Otherwise, the semiconductor device 300 is the same as the semiconductor device 100.

In the semiconductor device 300, the p-type pillar region 24 is electrically connected with the source electrode 12 via the p-type base region 22. The p-type base region 22 includes the first region 22a and the second region 22b. The lower end of the first region 22a is positioned higher than the upper end of the p-type pillar region 24. The lower end of the second region 22b is positioned lower than the upper end of the p-type pillar region 24. The second region 22b is arranged with the p-type pillar region 24 in the second and third directions D2 and D3.

The gate electrode 13 is positioned between the first region 22a and the second region 22b in the second and third directions D2 and D3. The upper end of the p-type pillar region 24 is positioned between the second region 22b and the n-type drift region 21 in the second and third directions D2 and D3. The first region 22a functions as a channel. The second region 22b does not function as a channel.

### First Manufacturing Method

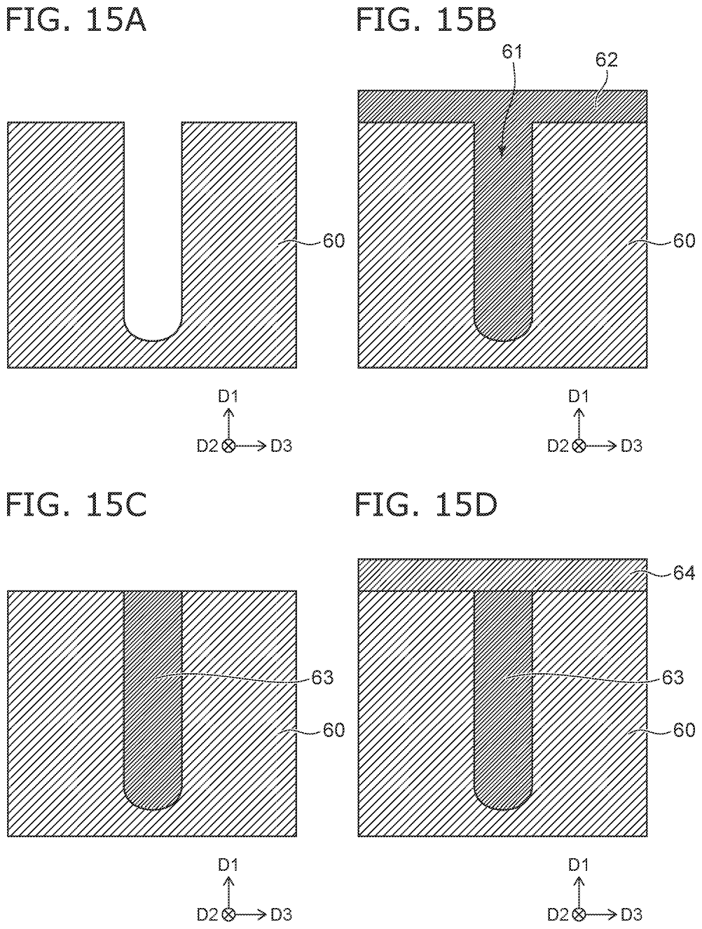

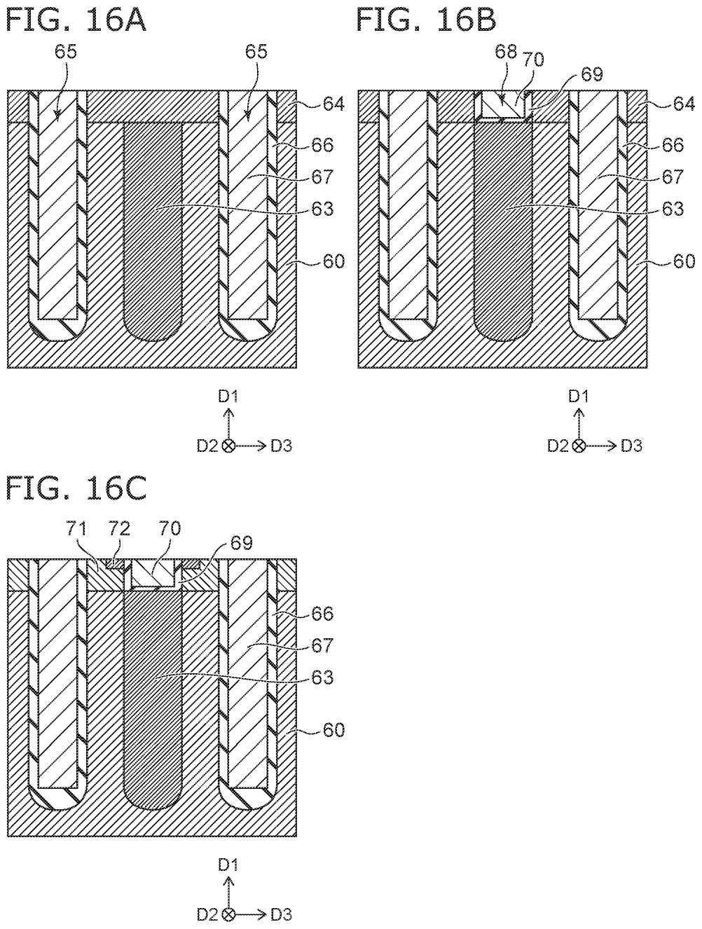

FIGS. 15A to 15D and FIGS. 16A to 16C are cross-sectional views illustrating an example of a manufacturing method of a semiconductor device according to an embodiment.

As illustrated in FIGS. 15A to 15D and FIGS. 16A to 16C, the first manufacturing method includes a first process, a second process, a third process, and a fourth process.

In the first process, a pillar region 63 of the second conductivity type (e.g., the p-type) is formed in a semiconductor region 60 of the first conductivity type (e.g., the n-type). In the second process, a first conductive part 67 is formed adjacent to the pillar region 63. The second process is performed after the first process. In the third process, a second conductive part 70 is formed on the pillar region 63. The third process is performed after the second process. In the fourth process, a diffusion layer is formed. The fourth process is performed after the third process. FIGS. 15A to 15C correspond to the first process. FIGS. 15D and 16A correspond to the second process. FIG. 16B corresponds to the third process. FIG. 16C corresponds to the fourth process. The processes will now be described.

In the first process, first, as illustrated in FIG. 15A, a trench 61 is formed in the semiconductor region 60 by removing a portion of the semiconductor region 60. For example, the trench 61 is formed by etching, etc.

Then, in the first process as illustrated in FIG. 15B, a semiconductor layer 62 is formed inside the trench 61 and on the semiconductor region 60. For example, the semiconductor layer 62 is formed by CVD (Chemical Vapor Deposition), etc.

Then, in the first process as illustrated in FIG. 15C, the portion of the semiconductor layer 62 formed on the semiconductor region 60 is removed. As a result, the portion of the semiconductor layer 62 formed inside the trench 61 remains to become the pillar region 63. The semiconductor region 60 corresponds to the n⁻-type drift region 21 described above. The pillar region 63 corresponds to the p-type pillar region 24 described above. For example, the portion of the semiconductor layer 62 formed on the semiconductor region 60 is removed by CMP (Chemical Mechanical Polishing), etc.

In the second process, first, as illustrated in FIG. 15D, a semiconductor layer 64 is formed on the pillar region 63 and on the semiconductor region 60. The semiconductor layer 64 may be a non-doped semiconductor layer to which an impurity is not added, may be a semiconductor layer to which a p-type impurity is added, or may be a semiconductor layer to which an n-type impurity is added. For example, the semiconductor layer 64 is formed by CVD, etc.

Then, in the second process as illustrated in FIG. 16A, the first conductive part 67 is formed adjacent to the pillar region 63. More specifically, first, a trench 65 is formed adjacent to the pillar region 63 by removing a portion of the semiconductor region 60 and a portion of the semiconductor layer 64 adjacent to the pillar region 63. Then, an insulating layer 66 is formed inside the trench 65 along the sidewall and bottom of the trench 65. Then, the first conductive part 67 is formed inside the insulating layer 66 along the sidewall and bottom of the insulating layer 66. The insulating layer 66 corresponds to the FP insulating part 32 described above. The first conductive part 67 corresponds to the FP electrode 14 described above. For example, the trench 65 is formed by etching, etc. For example, the insulating layer 66 is formed by thermal oxidation, etc. For example, the first conductive part 67 is formed by a combination of CVD and etching, etc.

In the third process as illustrated in FIG. 16B, the second conductive part 70 is formed on the pillar region 63. More specifically, first, a trench 68 is formed on the pillar region 63 by removing a portion of the semiconductor layer 64 on the pillar region 63. Then, an insulating layer 69 is formed inside the trench 68 along the sidewall and bottom of the trench 68. Then, the second conductive part 70 is formed inside the insulating layer 69 along the sidewall and bottom of the insulating layer 69. The insulating layer 69 corresponds to the gate insulating part 31 described above. The second conductive part 70 corresponds to the gate electrode 13 described above. For example, the trench 68 is formed by etching, etc. For example, the insulating layer 69 is formed by thermal oxidation, etc. For example, the second conductive part 70 is formed by a combination of CVD and etching, etc.

In the fourth process as illustrated in FIG. 16C, a diffusion layer is formed in the semiconductor layer 64. More specifically, a semiconductor region 71 is formed by implanting an impurity of the second conductivity type into the semiconductor layer 64; and a semiconductor region 72 is formed by implanting an impurity of the first conductivity type into a portion of the semiconductor region 71. The semiconductor region 71 corresponds to the p-type base region 22 described above. The semiconductor region 72 corresponds to the n⁺-type source region 23 described above.

When the semiconductor device includes the p⁺-type connection region 25 described above, for example, the p⁺-type connection region 25 is formed after the fourth process.

When setting the thickness of the p-type pillar region 24 to be different according to the position as described above, it is sufficient to form the trench 61 to have different widths when forming the trench 61 in the semiconductor region 60 in the first process. When setting the concentration of the impurity that forms donors in the p-type pillar region 24 to be different according to the position as described above, it is sufficient to form the semiconductor layer 62 (the pillar region 63) to have different impurity concentrations by dividing the formation of the semiconductor layer 62 inside the trench 61 and on the semiconductor region 60 into multiple formation steps in the first process.

According to the first manufacturing method, a semiconductor device can be easily manufactured in which the p-type pillar region 24 (the pillar region 63) is located under the gate electrode 13 (the second conductive part 70). Accordingly, a semiconductor device can be easily manufactured in which the on-resistance can be reduced.

### Second Manufacturing Method

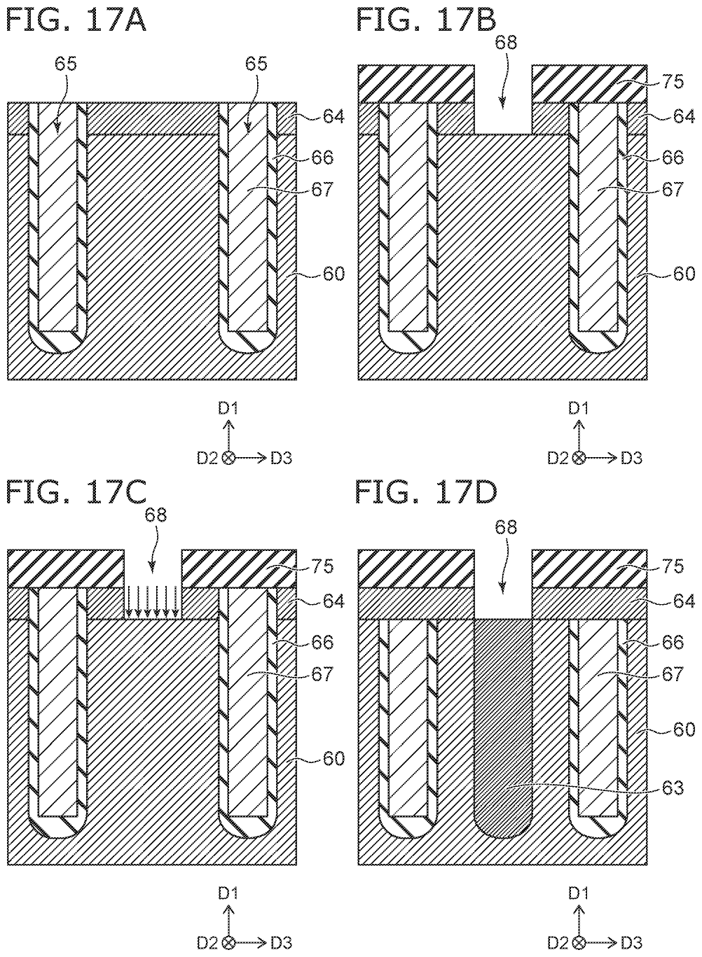

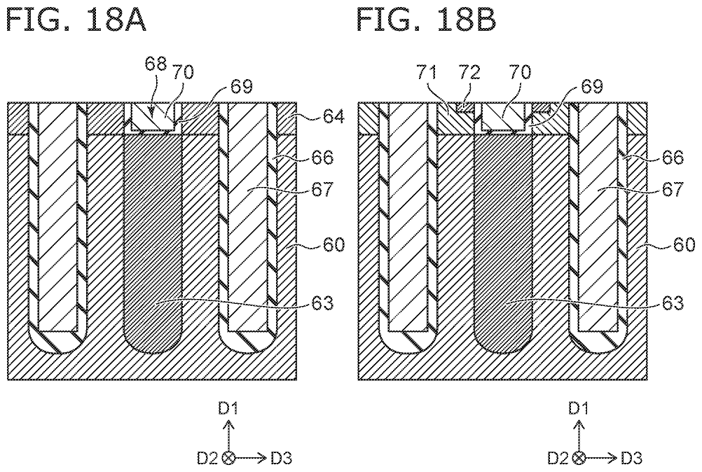

FIGS. 17A to 17D, FIG. 18A, and FIG. 18B are cross-sectional views illustrating another example of a manufacturing method of the semiconductor device according to the embodiment.

As illustrated in FIGS. 17A to 17D, FIG. 18A, and FIG. 18B, the second manufacturing method includes a first process, a second process, a third process, and a fourth process.

In the first process, the first conductive part 67 is formed in the semiconductor region 60 of the first conductivity type (e.g., the n-type). In the second process, the pillar region 63 of the second conductivity type (e.g., the p-type) is formed adjacent to the first conductive part 67. The second process is performed after the first process. In the third process, the second conductive part 70 is formed on the pillar region 63. The third process is performed after the second process. In the fourth process, a diffusion layer is formed. The fourth process is performed after the third process. FIG. 17A corresponds to the first process. FIGS. 17B to 17D correspond to the second process. FIG. 18A corresponds to the third process. FIG. 18B corresponds to the fourth process. The processes will now be described. The formation, removal, and the like of the portions can be performed similarly to the first manufacturing method.

In the first process as illustrated in FIG. 17A, the first conductive part 67 is formed in the semiconductor region 60. More specifically, first, the semiconductor layer 64 is formed on the semiconductor region 60. Then, the trench 65 is formed in the semiconductor region 60 and the semiconductor layer 64 by removing a portion of the semiconductor region 60 and a portion of the semiconductor layer 64. Then, the insulating layer 66 is formed inside the trench 65 along the sidewall and bottom of the trench 65. Then, the first conductive part 67 is formed inside the insulating layer 66 along the sidewall and bottom of the insulating layer 66.

In the second process, first, as illustrated in FIG. 17B, an oxide film 75 is formed on the semiconductor layer 64. Then, the trench 68 is formed adjacent to the first conductive part 67 by removing a portion of the semiconductor layer 64 and a portion of the oxide film 75 adjacent to the first conductive part 67. The semiconductor region 60 is exposed by forming the trench 68.

Then, in the second process as illustrated in FIG. 17C, an impurity of the second conductivity type is implanted into the semiconductor region 60 via the trench 68. Then, activation anneal is performed to form the pillar region 63 adjacent to the first conductive part 67 as illustrated in FIG. 17D.

In the third process as illustrated in FIG. 18A, the second conductive part 70 is formed on the pillar region 63. More specifically, first, the oxide film 75 is removed. Then, the insulating layer 69 is formed inside the trench 68 along the sidewall and bottom of the trench 68. Then, the second conductive part 70 is formed inside the insulating layer 69 along the sidewall and bottom of the insulating layer 69. For example, the oxide film 75 is removed by etching, etc.

In the fourth process as illustrated in FIG. 18B, a diffusion layer is formed in the semiconductor layer 64. The fourth process can be performed similarly to the fourth process of the first manufacturing method.

When the semiconductor device includes the p⁺-type connection region 25 described above, for example, the p⁺-type connection region 25 is formed after the fourth process.

When setting the thickness of the p-type pillar region 24 to be different according to the position as described above, it is sufficient to form the trench 68 to have different widths when forming the trench 68 adjacent to the first conductive part 67 in the second process. When setting the concentration of the impurity that forms donors in the p-type pillar region 24 to be different according to the position as described above, it is sufficient to form the pillar region 63 to have different impurity concentrations by dividing the implantation of the second-conductivity-type into the semiconductor region 60 via the trench 68 into multiple formation steps in the second process.

According to the second manufacturing method, a semiconductor device can be easily manufactured in which the p-type pillar region 24 (the pillar region 63) is located under the gate electrode 13 (the second conductive part 70). Accordingly, a semiconductor device can be easily manufactured in which the on-resistance can be reduced.

In the embodiments above, the relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured by, for example, SIMS (secondary ion mass spectrometry).

Embodiments may include the following configurations.

### Configuration 1

A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region selectively located on the second semiconductor region, the third semiconductor region being of the first conductivity type;
a second electrode located on the third semiconductor region, the second electrode being electrically connected with the third semiconductor region;
a third electrode arranged with the second semiconductor region in a second direction and a third direction, the second direction being perpendicular to a first direction, the first direction being from the first electrode toward the second electrode, the third direction being perpendicular to the first and second directions;
a first insulating part located between the second semiconductor region and the third electrode in the second and third directions;
a fourth electrode arranged with the first semiconductor region and the third electrode in the second and third directions;
a second insulating part located between the first semiconductor region and the fourth electrode and between the third electrode and the fourth electrode in the second and third directions; and
a fourth semiconductor region located under the third electrode, the fourth semiconductor region being electrically connected with the second electrode, the fourth semiconductor region being of the second conductivity type.

### Configuration 2

The device according to configuration 1, wherein
a lower end of the fourth semiconductor region is positioned lower than a lower end of the fourth electrode.

### Configuration 3

The device according to configuration 1 or 2, further comprising:
a fifth semiconductor region located on the second semiconductor region and arranged with the third electrode in the second and third directions,
the fifth semiconductor region being of the second conductivity type,
the fourth semiconductor region being electrically connected with the second electrode via the second and fifth semiconductor regions.

### Configuration 4

The device according to configuration 1 or 2, further comprising:
a fifth semiconductor region located on the fourth semiconductor region and arranged with the third electrode in the second and third directions,
the fifth semiconductor region being of the second conductivity type,
the fourth semiconductor region being electrically connected with the second electrode via the fifth semiconductor region,
the third electrode including
   a first electrode region extending along the second direction, and
   a second electrode region extending along a fourth direction, the fourth direction being perpendicular to the first direction and crossing the second direction,
the fifth semiconductor region being arranged with the first electrode region in the second direction and arranged with the second electrode region in the fourth direction.

### Configuration 5

The device according to any one of configurations 1 to 4, wherein
the second insulating part includes:
   a first insulating region extending along the second direction; and
   a second insulating region extending along a fourth direction, the fourth direction being perpendicular to the first direction and crossing the second direction,
the fourth semiconductor region includes:
   a first portion extending along the second direction; and
   a second portion extending along the fourth direction,
a thickness of the first insulating region is less than a thickness of the second insulating region, and
a thickness of the first portion is greater than a thickness of the second portion.

### Configuration 6

The device according to any one of configurations 1 to 5, wherein
the second insulating part includes:
   a first insulating region extending along the second direction; and
   a second insulating region extending along a fourth direction, the fourth direction being perpendicular to the first direction and crossing the second direction,
the fourth semiconductor region includes:
   a first portion extending along the second direction; and
   a second portion extending along the fourth direction,
a thickness of the first insulating region is less than a thickness of the second insulating region, and
a concentration of an impurity of the second conductivity type in the first portion is greater than a concentration of an impurity of the second conductivity type in the second portion.

### Configuration 7

A manufacturing method of a semiconductor device, the method comprising:
a first process of forming a pillar region of a second conductivity type in a semiconductor region of a first conductivity type;
a second process of forming a first conductive part adjacent to the pillar region; and
a third process of forming a second conductive part on the pillar region.

### Configuration 8

A manufacturing method of a semiconductor device, the method comprising:
a first process of forming a first conductive part in a semiconductor region of a first conductivity type;
a second process of forming a pillar region of a second conductivity type adjacent to the first conductive part; and
a third process of forming a second conductive part on the pillar region.

Thus, according to embodiments, a semiconductor device and a manufacturing method of a semiconductor device can be provided in which the on-resistance can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region selectively located on the second semiconductor region, the third semiconductor region being of the first conductivity type;
a second electrode located on the third semiconductor region, the second electrode being electrically connected with the third semiconductor region;
a third electrode arranged with the second semiconductor region in a second direction and a third direction, the second direction being perpendicular to a first direction, the first direction being from the first electrode toward the second electrode, the third direction being perpendicular to the first and second directions;
a first insulating part located between the second semiconductor region and the third electrode in the second and third directions;
a fourth electrode arranged with the first semiconductor region and the third electrode in the second and third directions;
a second insulating part located between the first semiconductor region and the fourth electrode and between the third electrode and the fourth electrode in the second and third directions; and
a fourth semiconductor region located under the third electrode, the fourth semiconductor region being electrically connected with the second electrode, the fourth semiconductor region being of the second conductivity type.

2. The device according to claim 1, wherein
a lower end of the fourth semiconductor region is positioned lower than a lower end of the fourth electrode.

3. The device according to claim 1, further comprising:
a fifth semiconductor region located on the second semiconductor region and arranged with the third electrode in the second and third directions,
the fifth semiconductor region being of the second conductivity type,
the fourth semiconductor region being electrically connected with the second electrode via the second and fifth semiconductor regions.

4. The device according to claim 1, further comprising:
a fifth semiconductor region located on the fourth semiconductor region and arranged with the third electrode in the second and third directions,
the fifth semiconductor region being of the second conductivity type,
the fourth semiconductor region being electrically connected with the second electrode via the fifth semiconductor region,
the third electrode including
a first electrode region extending along the second direction, and
a second electrode region extending along a fourth direction, the fourth direction being perpendicular to the first direction and crossing the second direction,
the fifth semiconductor region being arranged with the first electrode region in the second direction and arranged with the second electrode region in the fourth direction.

5. The device according to claim 1, wherein
the second insulating part includes:
a first insulating region extending along the second direction; and
a second insulating region extending along a fourth direction, the fourth direction being perpendicular to the first direction and crossing the second direction,
the fourth semiconductor region includes:
a first portion extending along the second direction; and
a second portion extending along the fourth direction,
a thickness of the first insulating region is less than a thickness of the second insulating region, and
a thickness of the first portion is greater than a thickness of the second portion.

6. The device according to claim 1, wherein
the second insulating part includes:
a first insulating region extending along the second direction; and
a second insulating region extending along a fourth direction, the fourth direction being perpendicular to the first direction and crossing the second direction,
the fourth semiconductor region includes:
a first portion extending along the second direction; and
a second portion extending along the fourth direction,
a thickness of the first insulating region is less than a thickness of the second insulating region, and
a concentration of an impurity of the second conductivity type in the first portion is greater than a concentration of an impurity of the second conductivity type in the second portion.

7. A manufacturing method of a semiconductor device, the method comprising:
a first process of forming a pillar region of a second conductivity type in a semiconductor region of a first conductivity type;
a second process of forming a first conductive part adjacent to the pillar region; and
a third process of forming a second conductive part on the pillar region.

8. A manufacturing method of a semiconductor device, the method comprising:
a first process of forming a first conductive part in a semiconductor region of a first conductivity type;
a second process of forming a pillar region of a second conductivity type adjacent to the first conductive part; and
a third process of forming a second conductive part on the pillar region.
